(19) United States
(12) Patent Application Publication
(10) Pub. No.: US 2019/0171198 A1
(43) Pub. Date: Jun. 6, 2019

(54) SEMICONDUCTOR MANUFACTURING SYSTEM

(71) Applicant: FOXSEMICON INTEGRATED TECHNOLOGY, INC., Miao-Li Hsien (TW)

(72) Inventors: YI-CHUN CHIU, New Taipei (TW); CHUN-KAI HUANG, New Taipei (TW); CHIH-CHENG LU, Miaoli Hsien (TW); CHUN-CHUNG CHEN, Miaoli Hsien (TW); CHEN-TSU FU, New Taipei (TW); SHENG-FU TSAI, New Taipei (TW)

(21) Appl. No.: 15/990,708

(22) Filed: May 28, 2018

(30) Foreign Application Priority Data
Dec. 6, 2017 (TW) 106142828

(51) Int. Cl. G05B 23/02; H01L 21/677

(52) U.S. Cl. CPC G05B 23/0275; G05B 2219/45031; H01L 21/67763

(57) ABSTRACT

A semiconductor manufacturing system includes an operating terminal, a first controller, and a plurality of second controllers. The operating terminal controls a main controller. Each of the plurality of second controllers is electrically connected to the first controller. In an initial or default state, the operating terminal controls the first controller as a main controller, and when the first controller fails, the operating terminal controls one of the plurality of the second controllers as a main controller, the others of the plurality of second controllers being controlled by the main controller.

### FIELD

The subject matter generally relates to a semiconductor manufacturing system.

### BACKGROUND

In a semiconductor manufacturing system, a machine tool often includes a plurality of loading units, which includes boxes of semiconductor wafers. Each machine tool provides a network point for system connection. Further, a machine tool in a semiconductor processing system uses a main controller to control the plurality of loading units. Once the main controller fails, all electrical connections between the plurality of loading units and the semiconductor processing system will be terminated, thereby resulting in the plurality of loading units not working properly, and resulting in significant loss of semiconductor manufacturing. Improvement in the art is preferred.

### BRIEF DESCRIPTION OF THE DRAWINGS

Implementations of the present disclosure will now be described, by way of example only, with reference to the attached figures.

FIG. 1 is a schematic view of a first exemplary embodiment of a semiconductor manufacturing system of the present disclosure when a first controller is defined as a main controller.

FIG. 2 is a schematic view of semiconductor manufacturing system of FIG. 1 when the first controller fails and a second controller is defined as a main controller.

FIG. 3 is a schematic view of a second exemplary embodiment of a semiconductor manufacturing system of the present disclosure when a first controller is defined as a main controller.

FIG. 4 is a schematic view of semiconductor manufacturing system of FIG. 3 when the first controller fails and a second controller is defined as a main controller.

### DETAILED DESCRIPTION OF EMBODIMENTS

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising” when utilized, means “including, but not necessarily limited to”; it specifically indicates open-ended inclusion or membership in the so-described combination, group, series, and the like.

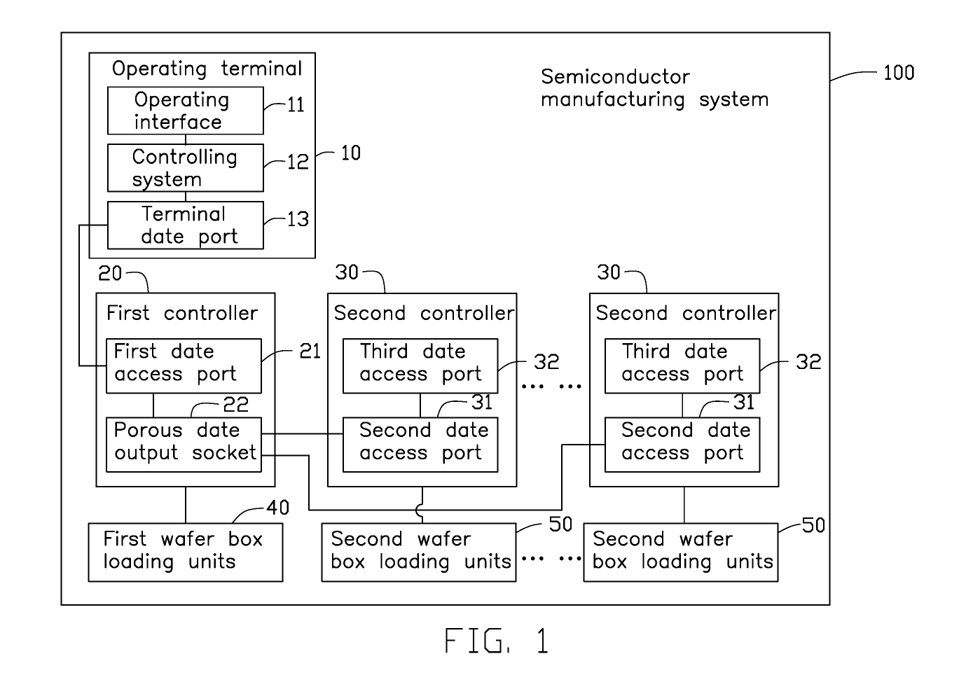

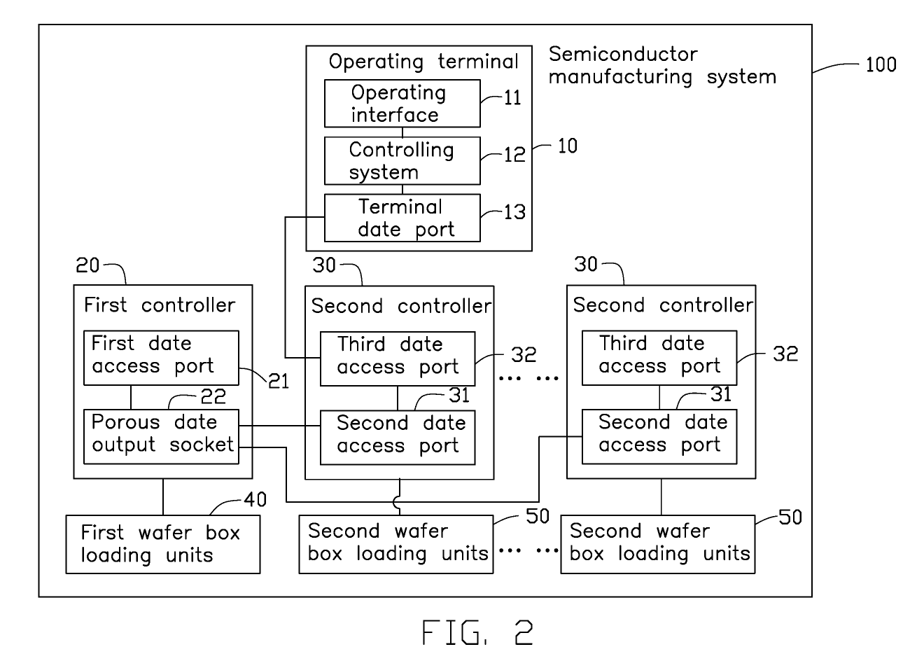

FIGS. 1 to 2 illustrate a first exemplary embodiment of a semiconductor manufacturing system 100. The semiconductor manufacturing system 100 includes an operating terminal 10, a first controller 20, a plurality of second controllers 30, a first wafer box loading unit 40, and a plurality of second wafer box loading units 50.

The operating terminal 10 includes an operating interface 11, a default controlling system 12, and a terminal data port 13.

Users can control the semiconductor processing system 100 through the operating interface 11. The user can turn on or turnoff the semiconductor processing system 100, invoke or save historical processing parameters, set up the first controller 20 or one of the plurality of second controllers 30 as a main controller, modify machining parameters of a main controller of the semiconductor processing system 100, etc.

The default controlling system 12 can be used to respond to operation of the operating interface 11 and to generate and send controlling data to the main controller of the semiconductor processing system 100.

The default controlling system 12 can set the first controller 20 or one of the plurality of second controllers 30 as slave controllers. The slave controllers are controlled from the main controller.

In one exemplary embodiment, the terminal data port 13 is used to electrically connect to the main controller of the semiconductor processing system 100, thereby realizing data transmission between the default controlling system 12 and the main controller of the semiconductor processing system 100.

The first controller 20 is electrically connected to each of the first wafer box loading unit 40. The first controller 20 controls operations of the first wafer box loading unit 40.

The first controller 20 includes a first data access port 21 and a multi-way data output socket 22.

The first data access port 21 is electrically connected to the terminal data port 13, thereby realizing data transmission between the first data access port 21 and the terminal data port 13.

The first data access port 21 is electrically connected to the multi-way data output socket 22, thereby realizing data transmission between the first data access port 21 and the multi-way data output socket 22.

The multi-way data output socket 22 is used to electrically connect the plurality of second controllers 30 to the first controller 20.

The plurality of second controllers 30 is electrically connected to the first controller 20.

The plurality of second controllers 30 and the plurality of second wafer box loading units 50 correspond to each other and are electrically connected with each other.

Each of the plurality of second controllers 30 is used to control and operate a second wafer box loading unit 50.

Each of the plurality of second controllers 30 includes a second data access port 31 and a third data access port 32 connected to the second data access port 31. All of the second data access ports 31 are electrically connected to the multi-way data output socket 22. The third data access port 32 can be connected to the terminal data port 13 when the first controller 20 fails.

FIG. 1 illustrates an initial state of the semiconductor manufacturing system 100 when the first controller 20 is defined as a main controller. The first data access port 21 is electrically connected to the terminal data port 13. The third data access port 32 of each of the second controllers 30 and the terminal data port 13 are disconnected.

The default controlling system 12 controls the first controller 20 as a main controller and directly controls the main controller. The first controller 20 controls the first wafer box loading unit 40. At the same time, the default controlling system 12 controls the plurality of second controllers 30 as slave controllers. The main controller controls the plurality of second controllers 30.

FIG. 2 illustrates a new state of the semiconductor manufacturing system 100 of FIG. 1 when the first controller 20 fails. When the first controller 20 fails, the first data access port 21 is manually disconnected from the terminal data port 13. The third data access port 32 of one of the second controller 30 is manually connected to the terminal data port 13. The default controlling system 12 directly controls the second controller 30 connected to the terminal data port 13 as a main controller. The second controller 30 controls the second wafer box loading units 50. At the same time, the default controlling system 12 controls the rest of the plurality of second controllers 30 as slave controllers. The main controller controls the rest of the plurality of second controllers 30.

When the second controller 30 that is the main controller fails, an operation similar to that of the previous paragraph is repeated, and another second controller 30 from the plurality of second controllers 30 is set at main, and the rest of the plurality of second controllers 30 is set at slave.

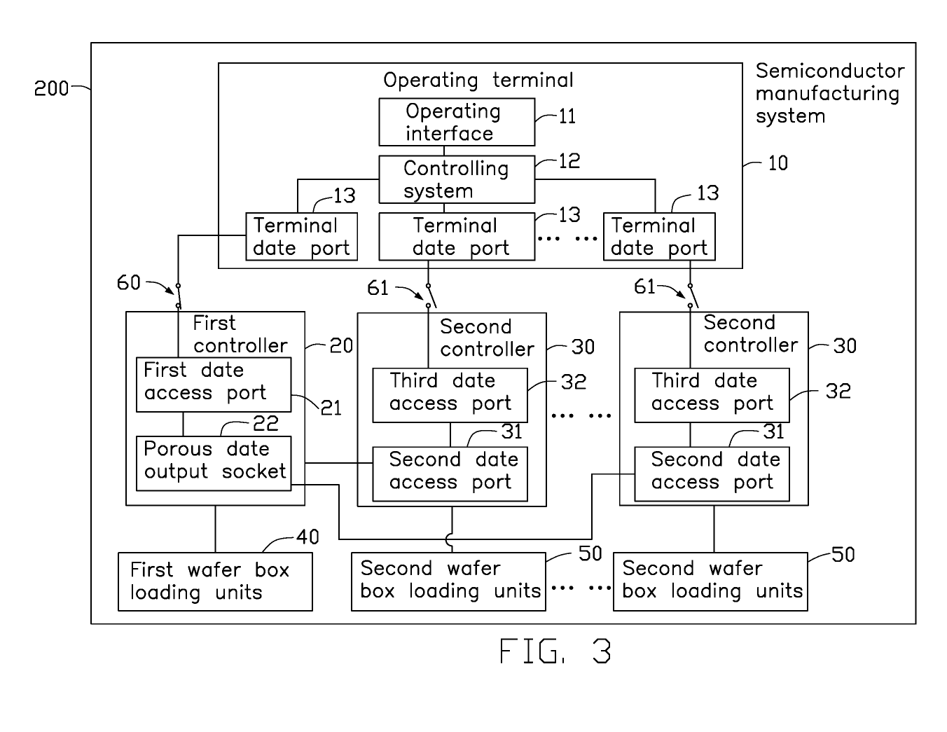

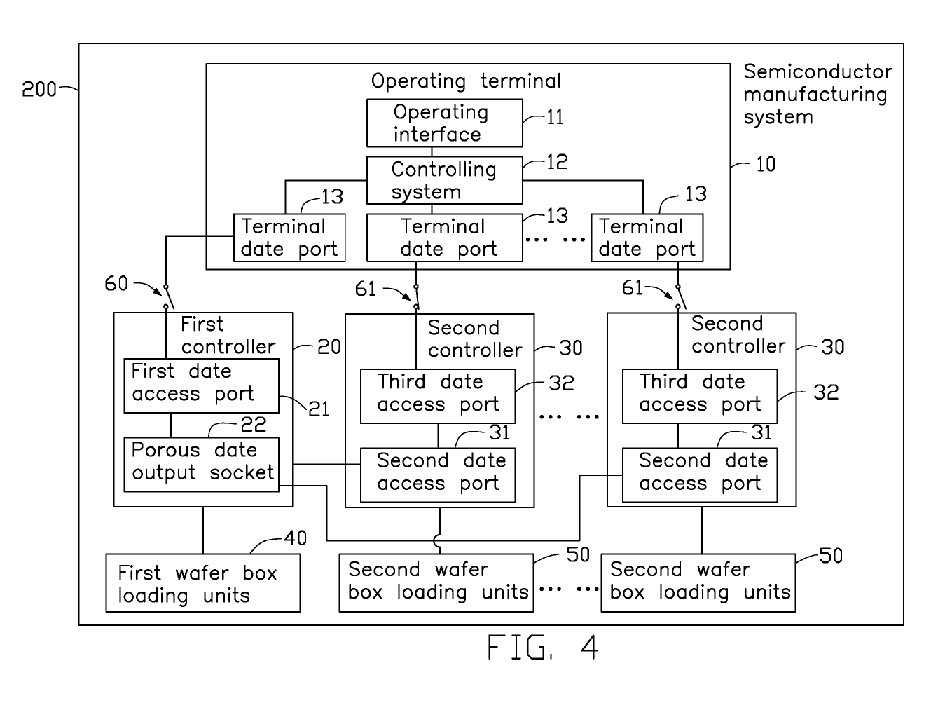

FIGS. 3 to 4 illustrate a second exemplary embodiment of a semiconductor manufacturing system 200. Structure of the semiconductor manufacturing system 200 is similar to the structure of the semiconductor manufacturing system 100 in the first exemplary embodiment. Differences between the semiconductor manufacturing system 200 and the semiconductor manufacturing system 100 are that the operating terminal 10 includes a plurality of terminal data ports 13, and the plurality of terminal data ports 13 is electrically connected to the first controller 20 and to the plurality of second controllers 30, by a first switch 60 and a second switch 61 respectively.

Number of the plurality of terminal data ports 13 is greater than or equal to sum of numbers of the first controllers 20 and number of the plurality of second controllers 30.

In at least one exemplary embodiment, the operating interface 11 is available for users to manually control the first switch 60 and the second switch 61 to be on or off.

FIG. 3 illustrates an initial state of the semiconductor manufacturing system 200 when the first controller 20 is defined as a main controller. The first switch 60 is manually switched on, and the first data access port 21 is electrically connected to the terminal data port 13. The plurality of the second switches 61 is manually switched off. The default controlling system 12 controls the first controller 20 as a main controller and directly controls the main controller. At the same time, the default controlling system 12 controls the plurality of second controllers 30 as slave controllers. The main controller controls the plurality of second controllers 30.

FIG. 4 illustrates a new state of the semiconductor manufacturing system 200 of FIG. 1 when the first controller 20 fails. When the first controller 20 fails, the first switch 60 is switched off, and the first data access port 21 is manually disconnected from the terminal data port 13. One of the plurality of the second switches 61 is switched on. The default controlling system 12 directly controls the second controller 30 connected to the terminal data port 13 as a main controller. At the same time, the default controlling system 12 controls the rest of the plurality of second controllers 30 to be slave controllers. The main controller controls the rest of the plurality of second controllers 30.

When the second controller 30 that is the main controller fails, an operation similar to that of the previous paragraph is repeated, and another second controller 30 from the plurality of second controllers 30 is set at main, and the rest of the plurality of second controllers 30 is set at slave.

In other exemplary embodiment, when the first controller 20 fails, the first switch 60 can remain on.

A third exemplary embodiment of a semiconductor manufacturing system. Structure of the semiconductor manufacturing system is similar to structure of the semiconductor manufacturing system 200 in the second exemplary embodiment. Differences between the semiconductor manufacturing system and the semiconductor manufacturing system 200 are that the switching on or the switching off of the first switch 60 and the second switch 61 is controlled from a procedure in the default controlling system 12. The default controlling system 12 can automatically select a normally-functioning controller as a main controller from the first controller 20 and the plurality of second controllers 30.

With the above configuration, the semiconductor manufacturing system includes a first controller 20 and a plurality of second controllers 30. Each of the plurality of second controllers 30 can be as a slave controller when the first controller 20 (main controller) is normally working, and one of the plurality of second controllers 30 can be a main controller when the first controller 20 fails. The semiconductor manufacturing system does not prevent the slave controller from operating due to a failure of the main controller, thus minimizing any damage caused by the failure of the main controller.

It is to be understood, even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A semiconductor manufacturing system, comprising:
an operating terminal, wherein the operating terminal controls a main controller;
a first controller; and
a plurality of second controllers, wherein the plurality of second controllers is electrically connected to the first controller; wherein in an initial state, the operating terminal controls the first controller as a main controller, when the first controller fails, the operating terminal controls one of the plurality of the second controller as a main controller, the others of the plurality of second controllers are controlled from the main controller.

2. The semiconductor manufacturing system of claim 1, wherein the semiconductor manufacturing system further comprises a first wafer box loading unit, the first wafer box loading unit is controlled from the first controller.

3. The semiconductor manufacturing system of claim 1, wherein the semiconductor manufacturing system further comprises a plurality of second wafer box loading units, the plurality of second wafer box loading units is controlled from the second controller.

4. The semiconductor manufacturing system of claim 3, wherein the plurality of second wafer box loading units is corresponding to the plurality of second controllers.

5. The semiconductor manufacturing system of claim 1, wherein the operating terminal comprises an operating interface, a controlling system, and a terminal data port, the operating interface is electrically connected to the controlling system, the controlling system is electrically connected to the terminal data port.

6. The semiconductor manufacturing system of claim 5, wherein in an initial state, the terminal data port is electrically connected to the first controller, when the first controller fails, the terminal data port is electrically connected to one of the plurality of second controllers.

7. The semiconductor manufacturing system of claim 6, wherein the first controller comprises a first data access port, in an initial state, the terminal data port is electrically connected to the first data access port.

8. The semiconductor manufacturing system of claim 7, wherein the first controller further comprises a multi-way data output socket electrically connected to the first data access port, wherein each of the second controllers comprises a second data access port and a third data access port connected to the second data access port, all of the second data access ports are electrically connected to the multi-way data output socket.

9. The semiconductor manufacturing system of claim 8, wherein when the first controller fails, the terminal data port is electrically connected to one of the third data access port.

10. The semiconductor manufacturing system of claim 8, wherein the operating terminal controls the first controller by a first switch, the operating terminal controls the plurality of the second controllers by a plurality of second switch.

11. The semiconductor manufacturing system of claim 10, wherein in an initial state, the first switch is switched on, the plurality of the second switches is switched off; wherein when the first controller fails, the first switch is switched off, one of the plurality of the second switches is switched on and others of the plurality of the second switches are still switched off.

12. The semiconductor manufacturing system of claim 10, wherein the first switch and the plurality of the second switches are manually controlled to switch on or switch off.

13. The semiconductor manufacturing system of claim 10, wherein the first switch and the plurality of the second switches are controlled to switch on or switch off a procedure in the operating terminal.

14. The semiconductor manufacturing system of claim 10, wherein the first switch is connected to the terminal data port and the first data access port.

15. The semiconductor manufacturing system of claim 10, wherein the plurality of the second switches is connected to the terminal data port and the third data access port of one of the second controllers.
